(19) United States
(12) Patent Application Publication
(10) Pub. No.: US 2026/0370860 A1
(43) Pub. Date: Nov. 19, 2026

(54) BLOCK PARTITIONING OF A DIGITAL TIME-VARYING SIGNAL

(71) Applicant: Fraunhofer-Gesellschaft zur Förderung der angewandten Forschung e.V., München (DE)

(72) Inventors: Jonathan PFAFF, Berlin (DE); Heiner KIRCHHHOFFER, Berlin (DE); Christian HELMRICH, Berlin (DE); Sophie PIENTKA, Berlin (DE); Christian RUDAT, Berlin (DE); Heiko SCHWARZ, Berlin (DE); Detlev MARPE, Berlin (DE); Thomas WIEGAND, Berlin (DE)

(21) Appl. No.: 19/737,733

(22) Filed: Jul. 10, 2026

Related U.S. Application Data
(63) Continuation of application No. PCT/EP2025/050710, filed on Jan. 13, 2025.

(30) Foreign Application Priority Data
Jan. 12, 2024 (EP) 24151745.7

(51) Int. Cl. H04N 19/44

(52) U.S. Cl. CPC H04N 19/44

(57) ABSTRACT

A decoder for decoding a digital time-varying signal from a data stream is presented. The decoder decodes the digital time-varying signal in temporal blocks; and decodes length information which indicates, for each temporal block, a selected block length out of a set of block lengths, and decodes the length information by decoding, for a predetermined temporal block, a variable-length binarization of a block length parameter comprised by the length information, and determines the selected block length for the predetermined temporal block based on the block length parameter, so that, for any two block lengths, a first bin string resulting in the determination of a shorter block length among the two block lengths, is longer, or equally long, than a second bin string resulting in the determination of a longer block length among the two block sizes. Additionally, encoder, method, data stream and computer program are presented.

### CROSS-REFERENCE TO RELATED APPLICATIONS

This application is a continuation of copending International Application No. PCT/EP2025/050710, filed Jan. 13, 2025, which is incorporated herein by reference in its entirety, and additionally claims priority from European Application No. EP24151745.7, filed Jan. 12, 2024, which is also incorporated herein by reference in its entirety.

Embodiments of the present invention disclosure relate to a decoder for decoding a digital time-varying signal, and an encoder for encoding a digital time-varying signal, in particular for decoding and encoding in a block-based manner and using block length information in the data stream, such as for coding of biomedical signals or seismic measurements.

### BACKGROUND OF THE INVENTION

Digital time-varying signals are commonly used for representation of various data such as biomedical signals or seismic measurements. During encoding and decoding, the signal may be split into various blocks to be encoded and decoded. For any block to be transmitted, a block length has to be encoded and decoded by the encoder and decoder. Existing approaches rely on fixing this block length, which results in a low flexibility, or encoding and decoding the block length just straight forward into the data stream, which results in bad coding compression. There is a need for finding a compromise between coding compression, also called (coding) efficiency, and flexibility while not being too computationally complex.

### SUMMARY

An embodiment may have a decoder for decoding a digital time-varying signal from a data stream, configured to decode the digital time-varying signal from the data stream in temporal blocks; and decoding length information from the data stream which indicates, for each temporal block, a selected block length out of a set of block lengths, wherein the decoder is configured to decode the length information from the data stream by decoding from the data stream, for a predetermined temporal block, a variable-length binarization of a block length parameter included by the length information, and determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

Another embodiment may have an encoder for encoding a digital time-varying signal into a data stream, configured to encode the digital time-varying signal into the data stream in temporal blocks; and encoding length information into the data stream which indicates, for each temporal block, a selected block length out of a set of block lengths, wherein the encoder is configured to encode the length information into the data stream by encoding into the data stream, for a predetermined temporal block, a variable-length binarization of a block length parameter included by the length information, and determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

According to another embodiment, a method for decoding a digital time-varying signal from a data stream may have the steps of: decoding the digital time-varying signal from the data stream in temporal blocks; and decoding length information from the data stream which indicates, for each temporal block, a selected block length out of a set of block lengths, wherein the method includes decoding of the length information from the data stream by decoding from the data stream, for a predetermined temporal block, a variable-length binarization of a block length parameter included by the length information, and determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

According to another embodiment, a method for encoding a digital time-varying signal into a data stream may have the steps of: encoding the digital time-varying signal into the data stream in temporal blocks; and encoding length information into the data stream which indicates, for each temporal block, a selected block length out of a set of block lengths, wherein the method includes encoding of the length information into the data stream by encoding into the data stream, for a predetermined temporal block, a variable-length binarization of a block length parameter included by the length information, and determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

Another embodiment may have a data stream encoded using the inventive method for encoding.

In accordance with a first aspect of the present inventive concept, a decoder for decoding a digital time-varying signal from a data stream is provided. The decoder is configured to decode the digital time-varying signal from the data stream in temporal blocks; and decoding length information from the data stream which indicates, for each temporal block, a selected block length out of a set of block lengths, wherein the decoder is configured to decode the length information from the data stream by decoding from the data stream, for a predetermined temporal block, a variable-length binarization of an block length parameter comprised by the length information, and determining the selected block length for the predetermined temporal block based on the block length parameter, so that, for any two block sizes in the set of block lengths, a first bin string of the block length parameter resulting in the determination of a shorter block length of the predetermined temporal block among the two block sizes, is longer, or equally long, than a second bin string of the block length parameter resulting in the determination of a longer block length of the predetermined temporal block among the two block sizes.

Analogue, relating to the first aspect of the invention, an encoder for encoding a digital time-varying signal into a data stream is defined. The encoder configured to encode the digital time-varying signal into the data stream in temporal blocks; and encoding length information into the data stream which indicates, for each temporal block, a selected block length out of a set of block lengths, wherein the encoder is configured to encode the length information into the data stream by encoding into the data stream, for a predetermined temporal block, a variable-length binarization of an block length parameter comprised by the length information, and determining the selected block length for the predetermined temporal block based on the block length parameter, so that, for any two block sizes in the set of block lengths, a first bin string of the block length parameter resulting in the determination of a shorter block length of the predetermined temporal block among the two block sizes, is longer, or equally long, than a second bin string of the block length parameter resulting in the determination of a longer block length of the predetermined temporal block among the two block sizes.

The first aspect of the present invention is based on the finding that when utilizing smaller or equally large bin strings for larger block lengths, the overall coding efficiency in coding a digital time-varying signal may be improved by providing slight advantages in coding the length information in terms of side information overhead for longer blocks than compared to smaller blocks, thereby increasing the fraction of longer blocks used to code the digital time-varying signal which longer blocks may result in improved coding efficiency. The concept defined herein goes against the intuitive concept of straight forward encoding and decoding the block length, where a short bin string equals a short block length and a long bin string equals a long block length.

Note, in the whole document, the terms length and size, or long and large have been used interchangeably.

An embodiment of the invention defines a decoder wherein the variable-length binarization is a truncated unary code and the decoder is configured to determining the selected block length for the predetermined temporal block based on the block length parameter, so that the selected block length is longer the shorter the bin string of the block length parameter is. Analogue, an encoder is defined, wherein the variable length binarization is a truncated unary code and the encoder is configured to determining the selected block length for the predetermined temporal block based on the block length parameter, so that the selected block length is the longer the shorter the bin string of the block length parameter is.

An embodiment of the invention defines a decoder, that is configured to determine the selected block length for the predetermined temporal block based on the block length parameter by deriving an exponent from the block length parameter and determining the selected block length to be 2 to a power determined by the exponent. Analogue, an encoder is defined, that is configured to determine the selected block length for the predetermined temporal block based on the block length parameter by deriving an exponent from the block length parameter and determining the selected block length to be 2 to a power determined by the exponent.

Signaling the block length via signaling the exponent so that the block length is 2 to the power of this exponent enables that the block length can be decoded and encoded more efficiently, since the set of block lengths can contain a wider range of possible block lengths, while maintaining a low cardinality. Furthermore, the needed calculation has little computational cost associated with it as the exponentation may be carried out using a simple bit shift, and therefore this embodiment of may lead to an improved compromise between the coding compression and the computational costs. The flexibility of an encoder and decoder according to this embodiment of the invention also stays high, since variable block sizes are possible over a wide range of numbers. Even further, restricting the block lengths to powers of two may fit to the usage of transform based coding of the blocks such as when using FFT for transformation.

An embodiment of the invention defines a decoder, that is configured to decode from the data stream an information on a maximum block length, and determine the selected block length for the predetermined temporal block based on the block length parameter by determining the selected block length to be 2 to a power equaling a binary logarithm of the maximum block length minus a subtrahend derived from the block length parameter. Analogue, an encoder is defined, that is configured to encode into the data stream an information on a maximum block length, and determine the selected block length for the predetermined temporal block based on the block length parameter by determining the selected block length to be 2 to a power equaling a binary logarithm of the maximum block length minus a subtrahend by the block length parameter.

By utilizing a maximal block length in the bit stream, the efficiency of the encoder or decoder can be increased. Since the maximum block length only needs to be encoded and decoded once or less frequently, the individual block length of a selected block can be determined with less additional information. The use of a maximum block length improves efficiency, reduces the need for extra information, and minimizes repetitive encoding/decoding. By setting the selected block length to be 2 to a power equaling a binary logarithm of the maximum block length minus a subtrahend derived from the block length parameter additional bits can be saved due to the usage of the maximum block length as a reference point.

An embodiment of the invention defines a decoder, that is configured to decode from the data stream an information on a maximum block length, and determine the selected block length for the predetermined temporal block based on the block length parameter by right-bit-shifting the maximum block length by a number of bit positions which is determined by the block length parameter. Analogue, an encoder is defined, that is configured to encode into the data stream an information on a maximum block length, and determine the selected block length for the predetermined temporal block based on the block length parameter by right-bit-shifting the maximum block length by a number of bit positions which is determined by the block length parameter.

By utilizing a maximal block length in the bit stream, the efficiency of the encoder or decoder can be increased. Since the maximum block length only needs to be encoded and decoded once, the individual block length of a selected block can be determined with less additional information. The maximum block length improves efficiency, reduces the need for extra information, and minimizes repetitive encoding/decoding. By using a right-bit-shifting operation, based on the maximum block length an especially efficient way of decoding and encoding a block length is disclosed herein.

An embodiment of the invention defines a decoder, that is configured to configured to decode from the data stream an information on a minimum block length, and wherein the variable length binarization is a truncated unary code and the decoder is configured to determine a truncation parameter of the truncated unary code based on the maximum block length and the minimum block length so that a number of bin strings of the truncated unary code equals a binary logarithm of the maximum block length minus a binary logarithm of the minimum block length plus 1. Analogue, an encoder is defined, that is configured to encode into the data stream an information on a minimum block length, and wherein the variable length binarization is a truncated unary code and the encoder is configured to determine a truncation parameter of the truncated unary code based on the maximum block length and the minimum block length so that a number of bin strings of the truncated unary code equals a binary logarithm of the maximum block length minus a binary logarithm of the minimum block length plus 1.

By utilizing a minimum block length in the bit stream, the efficiency of the encoder or decoder can be further increased. Since the minimum block length only needs to be encoded and decoded once, the individual block length of a selected block can be determined with less additional information. Together with the maximum block length, very little additional information about the selected block needs to be encoded and decoded from and into the data stream. Therefore, this approach represents an especially efficient implementation.

An embodiment of the invention defines a decoder, that is configured to decode the length information from the data stream further by check whether the selected block length as determined by the block length parameter times 1.5 does not exceed the maximum block length, if the selected block length as determined by the block length parameter times 1.5 does not exceed the maximum block length, decoding a flag comprised by the length information from the data stream, and increasing the selected block length to be 1.5 fold the selected block length as determined by the block length parameter in case of the flag having a first flag state. [e.g., and leaving the selected block length unincreased if the flag has a second flag state]. Analogue, an encoder is defined, that is configured to encode the length information into the data stream further by check whether the selected block length as determined by the block length parameter times 1.5 does not exceed the maximum block length, if the selected block length as determined by the block length parameter times 1.5 does not exceed the maximum block length, encoding a flag comprised by the length information into the data stream, and increasing the selected block length to be 1.5 fold the selected block length as determined by the block length parameter in case of the flag having a first flag state. [e.g., and leaving the selected block length unincreased if the flag has a second flag state].

Spending the flag represents an efficient way of also enabling the signalization of non-power-2 block lengths with nevertheless keeping the signalization overhead low.

A second aspect of the present inventive concept is related to a decoder for decoding a digital time-varying signal from a data stream, configured to decode the digital time-varying signal from the data stream in temporal blocks; and decoding length information from the data stream which indicates, for each temporal block, a selected block length, for example, out of a set of block lengths, wherein the decoder is configured to decode the length information from the data stream by decoding from the data stream, for a predetermined temporal block, one or more relative block length parameters comprised by the length information, and determining the selected block length of the predetermined temporal block based on a selected block length of a preceding temporal block and the one or more relative block length parameters. Analogue, relating to the second aspect of the invention, an encoder for encoding a digital time-varying signal into a data stream is defined. The encoder configured to encode the digital time-varying signal into the data stream in temporal blocks; and encoding length information into the data stream which indicates, for each temporal block, a selected block length, for example, out of a set of block lengths, wherein the encoder is configured to encode the length information into the data stream by encoding into the data stream, for a predetermined temporal block, one or more relative block length parameters comprised by the length information, and determining the selected block length of the predetermined temporal block based on a selected block length of a preceding temporal block and the one or more relative block length parameters.

The second aspect is based on the finding that the additional overhead associated with transmitting the block length information in order to allow for varying block lengths compared to a fixed length with the advantage of not having to transmit the length information, is more than compensated by coding/decoding the selected block length of a predetermined temporal block based on the selected block length of a preceding temporal block.

An embodiment of the invention defines a decoder, that is configured to derive from the one or more relative block length parameters a factor and determine the selected block length so that the selected block length of the predetermined temporal block becomes the selected block length of the preceding temporal block times the factor. Analogue, an encoder is defined, that is configured to derive from the one or more relative block length parameters a factor and determine the selected block length so that the selected block length of the predetermined temporal block becomes the selected block length of the preceding temporal block times the factor.

By encoding and decoding a factor representing the relationship between the previous block length and the selected block length provides an improved compromise between computational cost and efficiency can be achieved. Due to the minimal computational effort needed, both the encoder and decoder can perform these operations easily without creating performance bottlenecks. This approach can result in significant bit savings, as the factor is typically orders of magnitude smaller than the derived selected block length and is also smaller than the difference between the two block lengths.

An embodiment of the invention defines a decoder, that is configured to derive from the one or more relative block length parameters a number of bit shifts and determine the selected block length by applying the number of bit shifts onto the selected block length of the preceding temporal block. Analogue, an encoder is defined, that is configured to derive from the one or more relative block length parameters a number of bit shifts and determine the selected block length by applying the number of bit shifts onto the selected block length of the preceding temporal block.

Utilizing the block length parameter as a number of bit shifts to describe the relationship between the selected block length and the previous block length provides an improved compromise between computational cost and efficiency. Due to the minimal computational effort needed for bit shifting, both the encoder and decoder can perform the bit shift operation easily without creating performance bottlenecks. This approach can result in significant bit savings, as a number of bit shifts is naturally orders of magnitude smaller than the derived selected block length.

An embodiment of the invention defines a decoder, that is configured to, in decoding the one or more relative block length parameters, decode an equality flag comprised by the one or more relative block length parameters from the data stream, and if the equality flag has a first flag state, determine that the selected block length of the predetermined temporal block equals the selected block length of the preceding temporal block. Analogue, an encoder is defined, that is configured to, in encoding the one or more relative block length parameters, encode an equality flag comprised by the one or more relative block length parameters into the data stream, and if the equality flag has a first flag state, determine that the selected block length of the predetermined temporal block equals the selected block length of the preceding temporal block.

Usage of a flag to indicate the equality of the previous flag length and the selected block length can lead to large bit savings as it enables very efficient block length coding for steady state phases of the digital time-varying signal where no block variation is needed. The flag indicates an optimal solution for encoding and decoding, where most of the block lengths are the same but not all of them are. An encoder and/or decoder according to this embodiment provides flexibility when encoding and decoding the blocks, since variable block sizes are possible, while still providing good efficiency compared to hard encoding and decoding the selected block length.

An embodiment of the invention defines a decoder, wherein the magnitude parameter is a factor and the decoder is configured to determine the selected block length of the predetermined temporal block so that the selected block length of the predetermined temporal block becomes the selected block length of the preceding temporal block times the factor in case of the sign flag indicating the positive sign, and the selected block length of the preceding temporal block divided by the factor in case of the sign flag indicating the negative sign. Analogue, an encoder is defined, wherein the magnitude parameter is a factor and the encoder is configured to determine the selected block length of the predetermined temporal block so that the selected block length of the predetermined temporal block becomes the selected block length of the preceding temporal block times the factor in case of the sign flag indicating the positive sign, and the selected block length of the preceding temporal block divided by the factor in case of the sign flag indicating the negative sign.

Encoding and decoding the factor, through the magnitude parameter, representing the relationship between the previous block length and the selected block length provides an improved compromise between computational cost and efficiency. Due to the minimal computational effort needed, both the encoder and decoder can perform these operations easily without creating performance bottlenecks. This approach can result in significant bit savings, as the factor is typically orders of magnitude smaller than the derived selected block length.

An embodiment of the invention defines a decoder, that is configured to decode from the data stream an information on a maximum block length, and in case of the sign flag indicating the positive sign, decode the magnitude parameter from the data stream using a truncation unary code with setting a truncation parameter of the truncation unary code so that the subjecting the selected block length of the preceding temporal block to number of bit shifts to the left which equals a number of bin strings of the truncation unary code does not exceed the maximum block length, and/or decode from the data stream an information on a minimum block length, and in case of the sign flag indicating the negative sign, decode the magnitude parameter from the data stream using a truncation unary code with setting a truncation parameter of the truncation unary code so that the subjecting the selected block length of the preceding temporal block to number of bit shifts to the right which equals a number of bin strings of the truncation unary code does not fall below the minimum block length. Analogue, an encoder is defined, that is configured to encode into the data stream an information on a maximum block length, and in case of the sign flag indicating the positive sign, encode the magnitude parameter into the data stream using a truncation unary code with setting a truncation parameter of the truncation unary code so that the subjecting the selected block length of the preceding temporal block to number of bit shifts to the left which equals a number of bin strings of the truncation unary code does not exceed the maximum block length, and/or encode into the data stream an information on a minimum block length, and in case of the sign flag indicating the negative sign, encode the magnitude parameter into the data stream using a truncation unary code with setting a truncation parameter of the truncation unary code so that the subjecting the selected block length of the preceding temporal block to number of bit shifts to the right which equals a number of bin strings of the truncation unary code does not fall below the minimum block length.

Decoding and/or encoding the maximum block length and/or the minimum block length can lead to further efficiency gains. By incorporating meta information about the block length, allows to derive the selected block length from the data stream with a smaller individual bin string. The meta information only needs to be transmitted once and can be utilized for every block that gets decoded and/or encoded, depicting a highly efficient system.

A third aspect of the present inventive concept is related to a decoder for decoding a multi-channel digital signal from a data stream, configured to decode coded channels representing the multi-channel digital signal from the data stream in temporal blocks with sequentially decoding from the data stream mutually temporally co-located temporal blocks of the coded channels before decoding any subsequent temporal block of the coded channels; and decoding length information from the data stream which indicates, for each temporal block, a selected block length out of a set of block lengths.

In an embodiment of the invention, the decoder of the third aspect is configured to further conform to a decoder according to the first or second aspect. Or in other words, a decoder further conforming to a decoder according to an embodiment following the first or second aspect of the invention.

As previously discussed, a decoder according to the first and second aspect provides a more efficient implementation of block length decoding. The inventors have found that a decoder confirming to the third aspect and the first or second aspect of the invention can utilize synergy effects between the different aspects of the invention and can achieve good coding efficiencies when it comes to block length decoding.

In accordance with embodiments of the present invention, in accordance with any of the previously discussed aspects, transform-based prediction residual coding is used to code the blocks of varying length and the transforms of the blocks do not mutually overlap. That is, the temporal blocks are non-overlapping and the decoder is configured to decode each of transform-coded temporal blocks of the temporal blocks of the digital time-varying signal by predicting the respective transform-coded temporal block using a selected prediction mode out of a set of prediction modes to obtain a prediction signal, decoding coefficients from the data stream, the coefficients representing a prediction residual signal of the respective transform-coded temporal block in a transform domain, subjecting the coefficients to a predetermined re-transformation from the transform domain to time domain to obtain a time-domain prediction residual signal representing a prediction residual signal of the respective transform-coded temporal block in a time domain, and correcting the prediction signal using the time-domain prediction residual signal, wherein the predetermined re-transformation is a non-overlapping transform. Analogue, an encoder is defined.

The transformation and retransformation allows representing and coding data in a more energy dense manner, which improves coding efficiency. Prediction signals can be derived from already decoded samples, wherein the prediction signal can be corrected by the prediction residual signal, which allows reducing the amount of data that needs to be coded and signaled. It has been recognized that the use of non-overlapping transforms allow reconstruction of temporal blocks without depending on an overlap (e.g., signal overlap) from neighboring temporal blocks. As a result, reconstruction can be completed earlier and a delay between encoder and decoder can be reduced. Furthermore, the coding of non-overlapping transforms can be performed with less complexity and can be less prone to errors.

Furthermore, coding flexibility may be improved, since non-overlapping transforms can be compatible with deblocking algorithms that do not rely on a formation of overlapping frame signals. Since the transforms do not overlap, a deblocking can be performed individually for a temporal block, without necessarily affecting (and/or delaying) a deblocking and/or decoding a neighboring block. For example, a deblocking of a previously decoded block may affect its overlap (e.g., signal overlap) with the currently decoded block, which may reduce coding accuracy (e.g., due to deviations in the signal overlap introduced by deblocking) or coding speed. The decoder may, for example, receive deblocking parameters for a current block and can perform a deblocking only for that block, which can reduce a decoding delay and may reduce of the formation of signal deviations that could be formed by the deblocking when combining overlapping signals (e.g., in the time domain). Furthermore, since the transforms do not overlap, an immediately preceding temporal block may be fully reconstructed (as well as deblocked) before coding the subsequent temporal block. As a result, the information of the fully reconstructed temporal block can be used as additional information to improve (and/or reduce signaling for) a deblocking of the currently coded temporal block (e.g., derive one or more deblocking parameters based on the preceding temporal block).

### BRIEF DESCRIPTION OF THE DRAWINGS

Embodiments of the present invention will be detailed subsequently referring to the appended drawings, in which:

FIG. 1 shows a schematic exemplary overview of possible framework or codec into which embodiments of the invention may be built into; and

FIG. 2a-c show a schematic view of a decoder and an encoder according to an embodiment of the first aspect of the present inventive concept; and

FIG. 3a-b shows a schematic view of a decoder and an encoder for de/encoding non-overlapping temporal blocks according to an embodiment of the invention; and

FIG. 4a-b shows a schematic view of a decoder and an encoder according to an embodiment of the second aspect of the present inventive concept.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

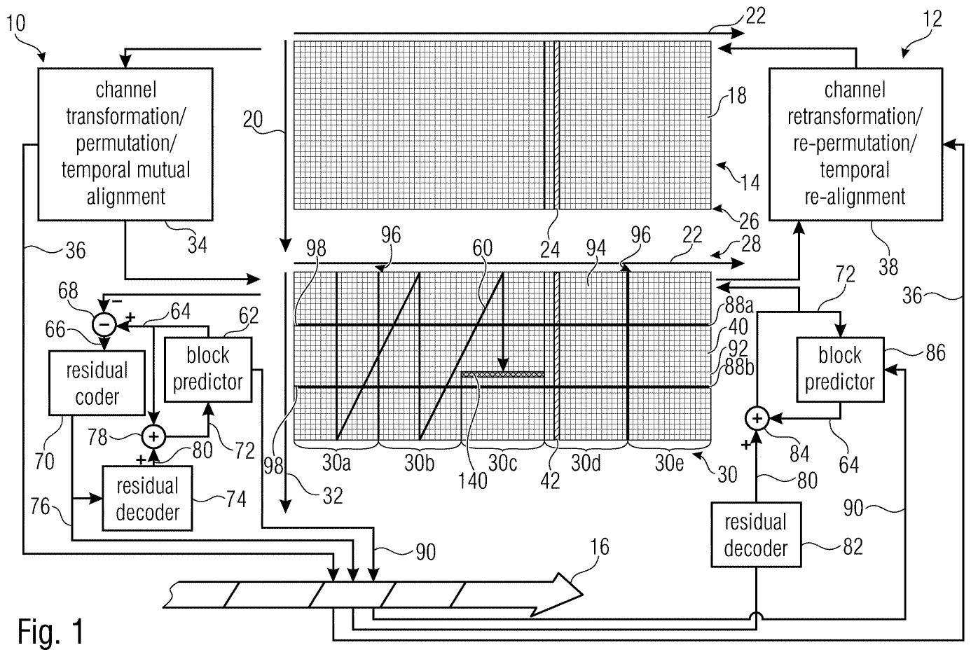

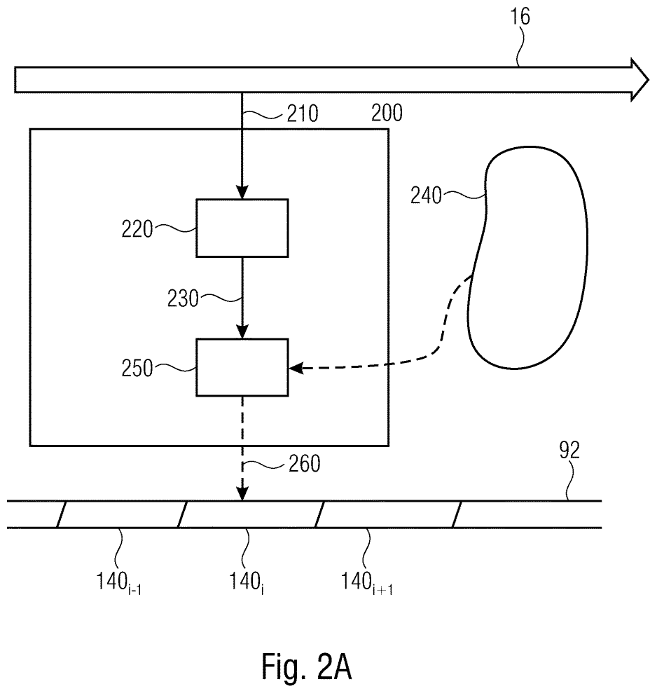

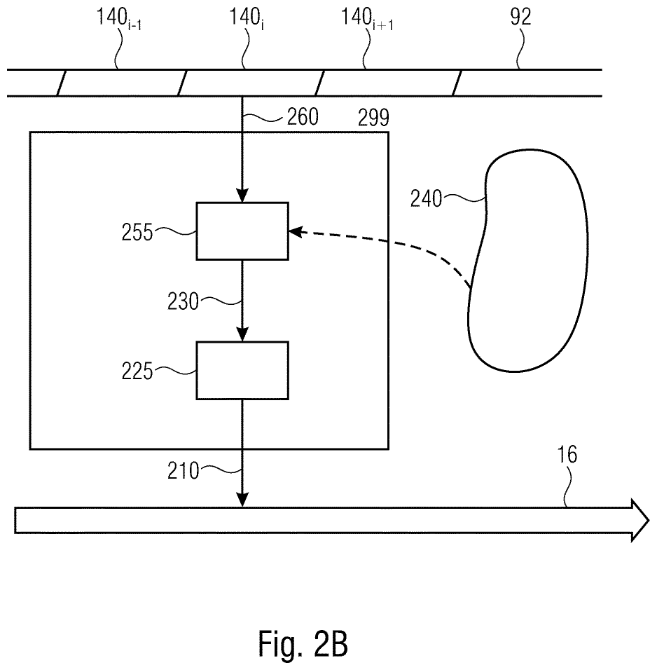

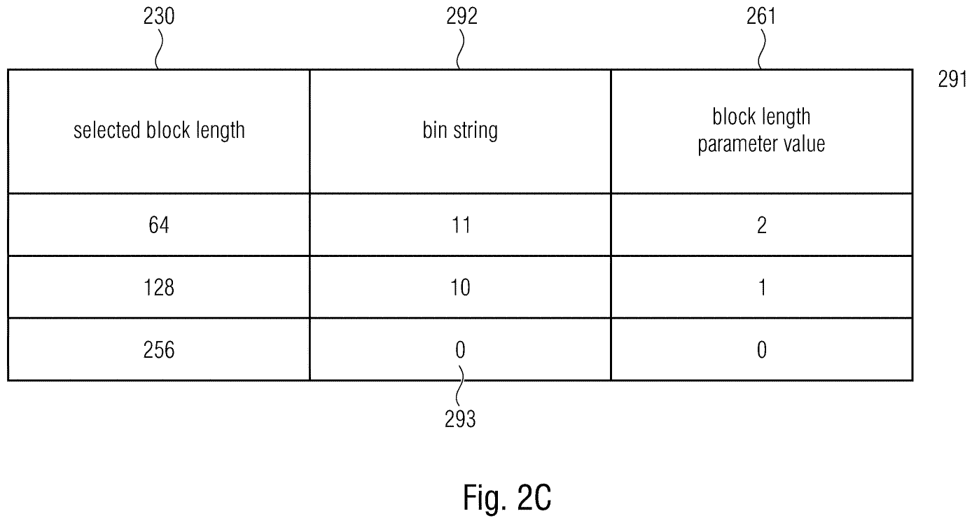

The description proceeds with a presentation of a possible framework or codec into which the embodiments described (e.g., with reference to FIG. 2 to 4) may be built into. Many details described in this framework are, however, optional when being combined with any of the described embodiments. To be more precise, the framework is described with respect to FIG. 1 which shows an encoder for encoding a multi-channel digital signal 14 into a data stream 16 as well as decoder 12 for decoding the multi-channel digital signal 14 from data stream 16. This description of FIG. 1 shall be seen as a presentation of new embodiments of the present application which result when combining any of the embodiments described above or any of the embodiments described subsequently is combined with the decoder 12 or encoder 10 of FIG. 1 either by adopting all details/functionalities described with respect to FIG. 1 or with leaving-out some of the details/functionalities described with respect to FIG. 1. Sometimes such “optional” features of FIG. 1 are explicitly identified as being optional with respect to the combination of the herein described embodiments, but the just-mentioned possible combinations of the subsequently explained embodiments with the description of FIG. 1 shall not be restricted to the these explicitly identified variations of FIG. 1 in terms of leaving-out certain features.

In FIG. 1, the multi-channel digital signal 14 is illustrated by way of an array of samples with the samples (e.g., wherein each sample defines a single value) being illustrated as small squares 18. Each line/row corresponds to a certain channel (e.g., 32 channels in FIG. 1, but a single channel or any other of channels may be used) of the multi-channel digital signal 14. Each channel of signal 14 may have associated therewith a respective channel ID and FIG. 1 shows these channels as being ordered according to their channel ID along vertical axis 20 which, thus, corresponds to a “source” channel axis 20. The horizontal axis 22 corresponds to time (e.g., in absolute time units such as μs or in units of samples, which may optionally all have the same duration, e.g., determined by a sampling rate) so that samples 18 forming one column, or being horizontally aligned, are samples belonging to one common time instant. Such set/column of temporally co-located samples 18 is exemplarily illustrated in FIG. 1 at 24.

Each channel, thus, forms a digital time-varying signal or time/amplitude or time-to-amplitude signal. The multi-channel digital signal 14 might have been obtained by at least one of Electrocardiography, Electroencephalography, Electromyography or seismic measurement. Differently speaking, the multi-channel digital signal might be a bio-physiological waveform data (e.g., a signal representative of a heart, brain, or eye activity) such as an electroencephalography (EEG) signal, an electrocardiogram (ECG), or an electromyography (EMG) signal, or seismic waveform data. However, each channel/signal might alternatively be another sort of waveform signal data such as scalar media data such as an audio signal and the signal 14 might be a multi-channel audio signal.

FIG. 1 illustrates the option according to which signal 14 is not coded directly, i.e., in the original domain 26, but in a so-called “coded domain” 28 (e.g., frequency domain) which might differ from the original domain 26 (e.g., time domain) by one or more of 1) channel transformation, 2) channel permutation and 3) temporal mutual channel alignment. The channel transformation, if applied, transforms, per sample time instant, a set or column 24 of samples from domain 26 to domain 28. Thus, in domain 28, the sample pitch and the time axis are the same as in domain 26, but the meaning of the channels is different, i.e., the “source” channels of domain 26 become transformed channels in domain 28. Accordingly, the vertical axis in FIG. 1 for domain 28 is denoted as 32. Note that the channel transformation might leave the number of channels unchanged so that there is the same number of channels in domain 26 as well as domain 28 (e.g., 32 channels in both domains 26, 28), but different approaches are also possible. Generally, the channel transformation would aim at reducing redundancy and trying to condense the channels' energy onto a fewer number of channels in domain 28. As said, the channel transformation is optional. Accordingly, in general terms, the channels in domain 28 are called “coded channels” in order to distinguish them from the “original” or “source” channels of digital signal 14 in domain 26. The permutation is also optional and may be used in combination with, or without, the channel transformation. If used in combination with the channel transformation, the permutation may be performed prior to and/or or subsequent to the channel transformation in order to permute/sort the source channels prior to transformation and the coded channels subsequent to the channel transformation. The channel transformation might be a DCT (discrete cosine transform), DST (discrete sine transform), FFT (fast fourier transform) or any other transformation. The temporal mutual alignment is also optional and might be seen as a constant temporal alignment between the source channels or the coded channels.

The module in encoder 10 performing the one or more of channel transformation, channel permutation and temporal mutual alignment is indicated in FIG. 1 as block 34. Side information 36 might be used in order to signal information on one or more of the following: 1) The channel transformation used, 2) information on the permutation(s) among the source channels and/or coded channels and 3) information on the mutual temporal alignment/delays between the source channels or coded channels wherein the temporal mutual alignment might be restricted to full sample precision. A corresponding block 38 in decoder 12 performs the reverse step, i.e., performs one or more of: 1) a channel retransformation, 2) a re-permutation of the source channels and/or coded channels and 3) a temporal re-alignment of the source channels or coded channels. Note, that if no channel transformation takes place, the coded channels are, in fact, equal to the source channels except for being temporally mutually aligned or being differently sorted due to permutation. Block 38 might be controlled by the before-mentioned side information 36.

Thus, the “actual coding” relates to the coded channels in domain 28. In the coded domain 28, the coded channels are depicted in FIG. 1 as lines or rows of samples 40, each extending along time axis 22, the coded channels being depicted one on top of the other along coded channel axis 32—potentially ordered according to a coded channel ID the have associated therewith—so as to result into an array of samples 40. Again, although FIG. 1 depicts the case that the number of source channels equals the number of coded channels, the number might be different. Further, if channel transformation is used, while there is no longer a clear association between source channels on the one hand and coded channels on the other hand, the temporal association remains: For each temporally co-located samples 24, there is a corresponding temporally co-located set 42 of samples 40 of the coded channels, wherein the set 42 in domain 28 is a column and might be a set of horizontally mutually offset samples in case of, and according to, the mutual temporal alignment, if applied. In case of FIG. 1, it has been assumed that no such temporal alignment took place so that both sets 42 and 24 are pure columns in the time/channel representation.

The actual coding is done in units of so-called temporal blocks 30. The term “temporal block” 30 is used so as to denote both a temporal portion of the multi-channel signal in domain 28, i.e., the set of coded channels, as well as a temporal portion of a certain coded channel. That is, for each temporal block 30, each coded channel has a temporal block such as block 140 depicted for some temporal block 30c and same are mutually co-located. The coding is done sequentially along these blocks 140, by following a coding/decoding order, which traverses the blocks 140 temporal block 30 by temporal block 30 with traversing temporally co-located blocks of the coded channels along a channel order corresponding to the order of the coded channels along axis 32. This coding/decoding order is illustrated in FIG. 1 at 60. That is, in case of temporal block 140 (e.g., temporal channel block) being the block currently to be coded/decoded, the previously decoded/encoded temporal blocks include all preceding temporal blocks of all coded channels as well as the temporally co-located temporal blocks of coded channels preceding the coded channel 92 of temporal block 140 in channel order. These previously coded/decoded temporal blocks and their samples are illustrated in FIG. 1 by way of shading. In this regard, note that in FIG. 1, merely one temporal block 140 has been illustrated explicitly in order to reduce the complexity of FIG. 1. Thus, in the specification herein, reference sign 140 is sometimes used to indicate the currently encoded/decoded temporal block or to stand representatively for all temporal blocks. Further, as depicted in FIG. 1, the partitioning of signal 14 into temporal blocks 30 and 140, respectively, might be done in a manner so that these blocks 30 and 140, respectively, are non-overlapping.

The actual coding in units of the temporal blocks 140 is performed predictively. That is, the encoder 10 comprises a block predictor 62 which predicts the samples of the currently coded temporal block 140, thereby yielding a prediction signal 64, and the prediction residual 66 formed by a subtraction between the actual sample values of temporal block 140 and the predicted samples of prediction signal 64 formed at a subtractor 68 is coded into the data stream 16 by residual coder 70. The residual coding in residual coder 70 may, or may not, involve a coding error by means of quantization. In any case, block predictor 62 uses the reconstructable version as being available by previously coded temporal blocks in order to obtain the prediction signal 64. This reconstructable version 72 might be derived at encoder 10 by means of a residual decoder 74 which reverses potential coding loss, such as quantization by means of dequantization, manifesting itself in the residual signal 76 coded into data stream 16, and an adder 78 which sums-up prediction signal 64 and the reconstructable residual signal 80 as obtained by residual decoder 74.

The decoder 12 decodes the coded channels from data stream 16 in a corresponding manner, i.e., in units of the temporal blocks 30 or in temporal blocks 140, respectively, and using predictive decoding. To this end, the decoder 12 comprises a residual decoder 82, an adder 84 and a block predictor 86 which correspond to, and are mutually connected in the same manner as, elements 74, 78 and 62 of encoder 10. That is, the residual decoder 82 derives from the residual signal 76 in data stream 16 the reconstructable residual signal 80 for a currently decoded temporal block 140 which is then subject to addition with prediction signal 64 derived by block predictor 86 for temporal block 140 on the basis of the reconstructed version 72 of previously decoded temporal blocks at adder 84. The output of adder 84, thus, yields the reconstructed version 72 of the currently decoded temporal block 140 and becomes part of the pool of already decoded samples of previously decoded temporal blocks when the temporal blocks of the coded channels are, in this manner, traversed along coding/decoding order 60 so as to reconstruct the coded channels in the coded domain 28.

In order to enable a high degree of random access capability, some of the temporal blocks 30 may be coded in a random access manner meaning that the coded channels therein are coded independent from previous temporal blocks 30. Imagine, for instance, that temporal blocks 30b and 30e are random access temporal blocks. Then, none of the temporal channel blocks 140 in temporal block 30b as well as 30e would depend on any preceding temporal block 140 such as none temporal block within temporal block 30a forming a coding dependency basis for any temporal channel block 140 in temporal block 30b and none of the temporal channel blocks 140 within temporal blocks 30a to 30d forming a coding dependency basis for any of the temporal channel blocks 140 within temporal block 30e. Thus, in other words, coding dependencies are restricted so as to not reach-out beyond the border of a random access temporal block 30b and 30e towards any preceding temporal block 30. Such restriction might also hold for intermediate temporal blocks 30c to 30d between random access temporal blocks 30b and 30e in that same may not depend on any temporal block preceding the leading one among the random access temporal blocks 30b and 30e, here block 30b. Accordingly, leading temporal borders of the random access temporal blocks 30b and 30e are indicated by bold lines in FIG. 1.

Further, it might be that the coding of the coded channels also interrupts or restricts inter-channel dependencies by coding one or more of the coded channels as random access coded channels so that coding dependencies of these random access coded channels, or even these random access coded channels and the intermediate coded channels therebetween, are restricted so as to not reach-out beyond such a random access coded channel toward any coded channel preceding that random access coded channel in channel order along axis 32. Two such random access coded channels 88a and 88b and their associated inter-channel dependency borders are illustrated in FIG. 1.

The block predictor 62 and 86 of encoder 10 and decoder 12, respectively, operate synchronously, i.e., they generate the same prediction signal 64 based on the previously encoded/decoded samples of previously encoded/decoded temporal blocks 140. On encoder side 10, the prediction for a certain temporal block 140 may be accompanied or determined by one or more prediction parameters. Same might be determined on encoder side based on a rate/distortion optimization. These prediction parameters 90 are coded into data stream 16 and they are decoded from data stream 16 and used by block predictor 86 so as to perform the same prediction.

It might be that encoder 10 and decoder 12 support more than one prediction mode. For instance, encoder 10 and decoder 12 may support an intra prediction mode (which mode may also be called block-copy mode) according to which the currently encoded/decoded temporal block 140 is predicted based on the reconstructable sample values of previously encoded/decoded temporal blocks of the same coded channel to which the currently encoded/decoded temporal block 140 belongs, which is coded channel 92 in the example of FIG. 1. Additionally or alternatively, encoder 10 and decoder 12 may support an inter-prediction mode (which mode may also be called cross-channel prediction mode) according to which the currently encoded/decoded temporal block 140 is predicted based on the reconstructable sample values of previously encoded/decoded temporal blocks of coded channels preceding—in coding order 32—the coded channel 92 to which the currently encoded/decoded temporal block 140 belongs. Additionally or alternatively, there may be a mixed prediction mode according to which the prediction signal 64 is obtained by both, reconstructed/reconstructable sample values of previously encoded/decoded temporal blocks of coded channel 92 itself as well as reconstructed/reconstructable sample values of coded channels preceding coded channel 92 in channel order along axis 32. Beyond this, there may be temporal blocks 140 which are coded without any prediction at encoder 10 and decoded without any prediction at decoder 12 such as the first temporal blocks in the tiles 94 resulting from mutually separating the temporal blocks by means of the random access borders 96 on the one hand and the random access channel borders 98 on the other hand. This corresponds to the prediction signal 64 being set to zero and this may form an additional mode which could be called bypass mode. Additionally, or alternatively, there may be other modes such as ones deriving a DC predictor or linear function predictor for block 64 based on immediately preceding samples of block 140. The prediction parameters 90 may, thus, contain for a currently encoded/decoded temporal block 140 a prediction mode flag or prediction mode indicator indicating the prediction mode to be used for this currently encoded/decoded temporal block 140 and, optionally, one or more parameters parameterizing the prediction mode to be used for this currently encoded/decoded temporal block 140.

The aforementioned coding dependencies ought not to cross any of the borders 96 and 98 not only result from the just-described sample prediction capabilities of block predictor 62 and 86, respectively, but may optionally also result from other mechanisms such as parameter prediction according to which parameters such as the aforementioned prediction parameters 90 for a certain temporal block 140 are predicted based on coding parameters conveyed in the data stream 16 for any previous temporal block, or context derivation for context-adaptive entropy coding/decoding any coding parameter such as the prediction parameters 90 or any other side information such as side information 76 and 36 for temporal block 140 based on any coding parameter conveyed in the data stream 16 for any preceding temporal block.

That is, summarizing, the encoder 10 encodes the multi-channel signal 14 by transferring it into the coded domain 28 and then coding the coded channels into data stream 16 in the just-described block-wise and predictive manner, wherein decoder 12 decodes the coded channels of coded domain 28 from data stream 16 and the corresponding block-wise and predictive manner with then gaining the multi-channel signal 14 in its original form 26 based on the coded channels in coded domain 28 by means of segment 38. As said, the channel transformation is optional and if not used, each sample 40 in the coded domain 28 really corresponds to one sample 18 in the original domain 26. If, further, the temporal mutual alignment is not used, each sample 40 exactly corresponds to a sample 18 in the original domain 26 at exactly the same time instant or, differently speaking, all temporally co-located samples 40 in coded domain 28 remain mutually temporally co-located in the original domain 26.

As mentioned before, FIG. 1 only represents a possible “framework” into which the previously described embodiments and the embodiments described subsequently may be built into. Many modifications may be performed with respect to FIG. 1, and some of these modifications might be mentioned in the subsequent description with respect to certain ones of the subsequently described embodiments, but these modifications shall then be treated as being also applicable with respect to other ones of the subsequently described embodiments. Further, as a final note, and without being treated as forming an exclusive list of further possible amendments of the description of FIG. 1, it shall be noted that the temporal blocks 30 might, other than illustrated in FIG. 1, vary in block length rather than being of a constant length as depicted in FIG. 1. For instance, encoder 10 may decide on the length of blocks 30 and signal the block length of blocks 30 (and the corresponding temporal blocks 140 of the coded channels) within data stream 16. Further, although not described before, it might be that residual coder and residual decoder 70 and 82 may use transform coding/decoding in order to convey the residual signal 76 in data stream 16. That is, the residual signal 80 may be conveyed in data stream 16 in transform domain by way of transform coefficients in residual signal 76. The transform domain might be a DCT, DST or an FFT. The transform may be non-overlapping, i.e. it may only transform residual signal 80 and its re-transform may only cover residual signal 76 within block 140, and/or may be non-windowed, i.e. the residual signal might be transformed without any transform window used to temporally shape the residual signal 80 before the transform. The transform domain, i.e. the transformation leading from time domain to transform domain which is used by the encoder to transform the prediction residual signal 80 to be coded und the corresponding re-transformation leading from transform domain to time domain which is used by the decoder to derive the prediction residual signal 80, or the transformation, might be selected from a set of available transforms including, for instance, one or more of 1) one or more DCTs, 2) one or more DSTs and 3) an identity transform according to which the prediction residual signal 80 is coded into the data stream 14 in time domain directly. Some deblocking processing might be used to avoid blocking artifacts. If, alternatively, an overlapped transform is used, an overlap-add processing with re-transforms of immediately preceding/succeeding temporal blocks of the same coded channel might be used in order to completely reconstruct the current temporal block's 140 residual signal 76. Besides such transform-(residual)-coded blocks there might be temporal blocks 140 which, additionally or alternatively, are coded using, besides the block prediction by block predictor 62/86—which could be called a primary prediction—a secondary sample-wise prediction of the residual samples in residual block 66 such as by predicting a current sample's residual sample by means of already decoded values of preceding—in sample coding order—residual samples in block 66 or 80, with then correcting same by means of a secondary-prediction-residual sample decoded from the data stream 16. The secondary-prediction-residual samples for such a block may be coded into the data stream en block in a transform domain or sample-wise in time domain.

The description now proceeds with a presentation of embodiments of the present invention. As indicated above, same may be built into the coding environment described above with respect to FIG. 1, but are not restricted thereto. For instance, while predictive block coding with transform based residual coding has been used, this is not mandatory, and the embodiments described below may use a different way of block coding. Moreover, overlapping transforms might be used alternatively. Further, some of the embodiments described below are not restricted to the coding of multiple channels, but relate to the coding of a digital time-varying signal such as one channel only. In any case, all details set out above, shall be understood as being transferable to the subsequently explained embodiments, individually and in any combination, and transfer represents another embodiment of the present application.

Embodiments of the invention or parts of it may also be entitled “block partitioning of a digital time-varying signal” they reveal, inter alias, an approach for block partitioning of a digital time-varying signal (e.g. the digital time-varying signal 92) such as biomedical waveform signals.

FIG. 2a shows a schematic view of a decoder 200 according to an embodiment of the first aspect of the present invention for decoding a digital time-varying signal 92 from a data stream 16. The decoder 200 comprises a block length parameter determinator 220, that can be configured to determine for each temporal block 140 a block length parameter 230 based on a variable-length binarization of the block length parameter comprised by the length information 210. The decoder 200 further comprises a block length determinator 250, that is configured to determine a selected block length 260 based on the block length parameter and a set of block lengths 240. The length information 210 may comprise multiple block length parameter 230 for multiple temporal blocks 140.

The decoder 200 may, for example, be configured to determine the selected block length for the predetermined temporal block based on the block length parameter, so that, for any two block lengths in the set of block lengths 240, a first bin string of the block length parameter 230 resulting in the determination of a shorter block length of the predetermined temporal 140ᵢ block among the two block lengths, is longer, or equally long, than a second bin string of the block length parameter 230 resulting in the determination of a longer block length of the predetermined temporal block 140ᵢ among the two block sizes.

For example, the decoder 200 may perform the length determination for the blocks 140 sequentially along the order of the blocks 140 in the data stream, i.e. in biostream order, which order may coincide with the presentation time order of the blocks.

The set of block lengths 240 may be known to the decoder 200 by default (and agreed between encoder and decoder by default) or may be determined on encoder side and be derived and decoded by the decoder from the data stream 16. Even alternatively, encoder and decoder may obtain knowledge on the set 240 allowed or available block lengths from a third entity.

FIG. 2b shows a schematic view of an encoder 299 according to an embodiment according to the first aspect of the invention for encoding a digital-time-varying signal 92 into a data stream 16, which fits to the decoder of FIG. 2a. For encoding a selected block length 260 of a predetermined temporal block 140ᵢ the encoder 299 can comprise an encoder block length parameter determinator 255, that can be configured to determine a block length parameter 230 based on the selected block length 260 and a set of block lengths 240. The encoder 299 can further comprise a length information determinator 225 that can be configured to determine a length information 210 on the basis of the block length parameter. The length information 210 can comprise a variable-length binarization of the block length parameter 230 of the predetermined temporal block 140ᵢ. The encoder 299 can be configured to encode the length information 210 into the data stream 16. The length information 210 may comprise multiple block length parameter 230 for multiple temporal blocks 140.

The encoder 299 may, for example, be configured to determine the block length parameter 230 for the predetermined temporal block 140ᵢ so that, for any two block lengths in the set of block lengths, a first bin string of the block length parameter resulting in the determination of a shorter block length of the predetermined temporal block among the two block lengths, is longer, or equally long, than a second bin string of the block length parameter 230 resulting in the determination of a longer block length of the predetermined temporal block 140ᵢ among the two block sizes. The length information 210 may comprise multiple block length parameter 230 for multiple temporal blocks 140.

As noted above, the embodiments of FIGS. 2a and 2b and the subsequently explained embodiments not necessarily adopt all features of FIG. 1. In order to specifically describe certain additional possible configurations of these embodiments, some notes are made which also introduce nomenclature used for the subsequent explanations. As described, the digital time-varying signal 92, which is also sometimes mentioned by X is coded and decoded by partitioning same into blocks, indicated as temporal blocks 140ᵢ in FIG. 1, and en/decoding the resulting block partitioning into/from a bitstream, namely data stream 16 in case of FIG. 1, and by employing the block partitioning for efficiently en/decoding a compressed (and potentially distorted) version of the samples of the blocks into/from the bitstream (e.g., data stream 16).

The decoder 200 which, as said, may be partially or completely embodied according to the decoder 12 of FIG. 1, may decode the block partitioning from the bitstream 16, namely from block information 210, and use the block partitioning to decode the compressed versions of the samples of the blocks 140 in order to reconstruct a (potentially distorted version of) X. Let Y denote the reconstructed/decoded digital time-varying signal 92, e.g. a reconstructed biomedical waveform signal, as it is decoded from the bitstream 16 and that corresponds to X. Let y_{i,j} be the sample of Y that corresponds to sample x_{i,j} of X.

The samples of Y are partitioned into a sequence of B blocks 140 which shall be denoted b₀ to b_{B-1} (e.g., temporal blocks 140i, with i∈[0, . . . , B−1]). A block bₖ (e.g., selected temporal block 140i/140k) can be described by the position of the first sample sₖ and by the length in sample-direction lₖ (e.g. the block length 260 of the temporal block 140k) so that block bₖ contains samples y_{i,j} with sₖ≤j<sₖ+lₖ and 0≤i<N. Furthermore, adjacent blocks (e.g., temporal blocks 140i−1 and 140ᵢ₊₁) shall contain adjacent samples. More precisely,

sₖ₊₁=sₖ+lₖ (1)

shall hold.

The block partitioning may be encoded into the bitstream as a sequence of lengths (e.g., in the form of length information 210) in sample-direction L which consists of lengths l₀ to l_{B-1}. The positions of the first samples sk can be reconstructed from (1) where s₀=0.

In accordance with an example, values for the block lengths lₖ (e.g., block length 260) are restricted to powers of 2. A particular block length (e.g., selected block length 260) may be encoded and/or decoded as a truncated unary codeword qₖ (e.g., corresponding to the block length parameter 230) that may indicate the number of right shifts to be applied to a predefined maximum allowed block length lₘₐₓ. I.e., lₖ=lₘₐₓ>>qₖ. A larger/longer block length parameter 230 may thereby correspond to a shorter particular/selected block length 260.

The truncation of the unary codeword may apply when lₖ equals a predefined minimum allowed block length lₘᵢₙ. For example, if lₘₐₓ=256 and lₘᵢₙ=64, the truncated unary codeword may be 0, 1, or 2, indicating a block length (e.g., block length 260) of 256, 128, or 64, respectively. A value of 2 for qₖ is then the truncated unary codeword (e.g., block length parameter 230), i.e. it consists of the binary sequence 11 (the terminating 0 is not encoded because the minimum allowed block length is already achieved).

FIG. 2c illustrates the usage of the truncated unary code for the binarization of the block length parameter 230 by showing a table 291 that exemplarily depicts the relation between the block length parameter's value 261 bin strings 292 and the selected block length 260. The bin strings 292 represent codewords of the binarization and are strings of bins 293 or bits 293 which are coded into and decoded from the data stream. Subsequently, when it is referred to position of a bin/bit, bit position, or bin positions, the position of a single bit 293, counting from the left, is to be understood. Here, a truncated unary code is used where each bin string 292 consists of qₖ 1 (namely at, if qₖ is larger than 0, bit positions 1 to qₖ) followed by a 0 (at bit position qₖ+1), except for the longest bin string 292 where qₖ equals 2, where the terminating zero is left off. Naturally, ones and zeros may be switched and naturally, the usage of a truncated unary code (or unary code in general) is merely an example. Table 291 reveals the association of the binarization's bin strings 292 to the block length parameter's values 261, namely that same is such that shorter selected block length values 260 are attributed to longer bin strings 292 and vice versa. The set of block lengths 240 would comprise [64, 128, 256]. The selected block length 260 are based on the block length parameter 230 (e.g., the truncated unary codeword qₖ), so that, for any two block lengths in the set of block lengths 240, a first bin string 292 of the block length parameter 230 resulting in the determination of a shorter block length of the predetermined temporal block 140i among the two block length, is longer, or equally long, than a second bin string 292 of the block length parameter 230 resulting in the determination of a longer block length of the predetermined temporal block 140i among the two block sizes.

While FIG. 2c shows illustrates the exploitation of the knowledge of the minimum block length 64 (e.g. lₘᵢₙ) in order to shorten one bin string 292, this feature may be left off, leading in the example of FIG. 2c to a bin string 292 for value 2 which would be 110.

The decoder 200 and encoder 299 may utilize binary context-adaptive entropy coding for the block length parameter 230, i.e. for en/decoding the bin strings 292. In an embodiment, the decoder 200 and encoder 299 may use separate context models of each bin position of the variable length binarization, e.g. one context for the first bin/bit 293 another for the second bin/bit 293 and so on, or at least one separate context for one bin position and another context for the other bin position(s), or spending sperate contexts for certain groups of bin positions.

The encoding and decoding of the block length parameter 230 (e.g. the truncated unary codeword qₖ) may, in particular, employ arithmetic coding and context modeling. A distinct context model may be used for each position in the unary codeword, or worded differently, a distinct context model may be used for each bin 293 of the bin string 292 that relates to the block length parameter 230, depending the position of the bin 293.

A maximum and a minimum value for lₖ may be encoded in the bitstream (e.g., data stream 16), thereby e.g. effectively defining set 240. For example, the maximum value lₘₐₓ may be restricted to a power of 2 and only the exponent to base 2 may be encoded using a fixed length integer representation. The minimum value lₘᵢₙ may be encoded by indicating a maximum allowed value qₘₐₓ so that lₘᵢₙ=lₘₐₓ>>qₘₐₓ. The minimum value lₘᵢₙ may also be encoded and decoded as an integer indicating the difference between the binary logarithm of the maximum block length minus the binary logarithm of the minimum block length.

Values for lₖ may, for example, either be powers of 2 or the 1.5-fold of powers of 2 (e.g. 16*1.5=24, or 32*1.5=48, the set of block lengths 240 could for example comprise {16, 24, 32, 48} and 64). A flag may be encoded and decoded after signaling lₖ which indicates that lₖ is multiplied with 1.5. This flag may not be encoded if the resulting block length lₖ (e.g., selected block length 260) would be larger than a predefined maximum block length lₘₐₓ.

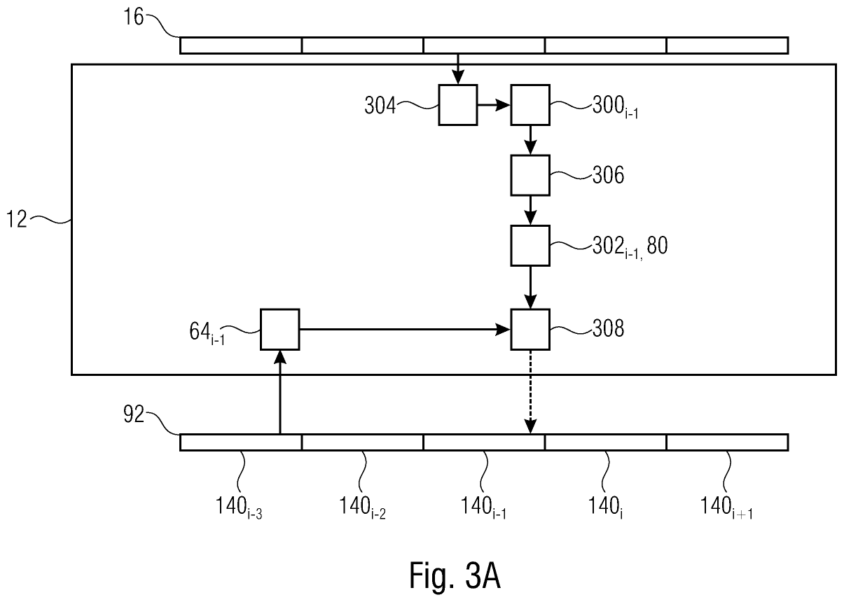

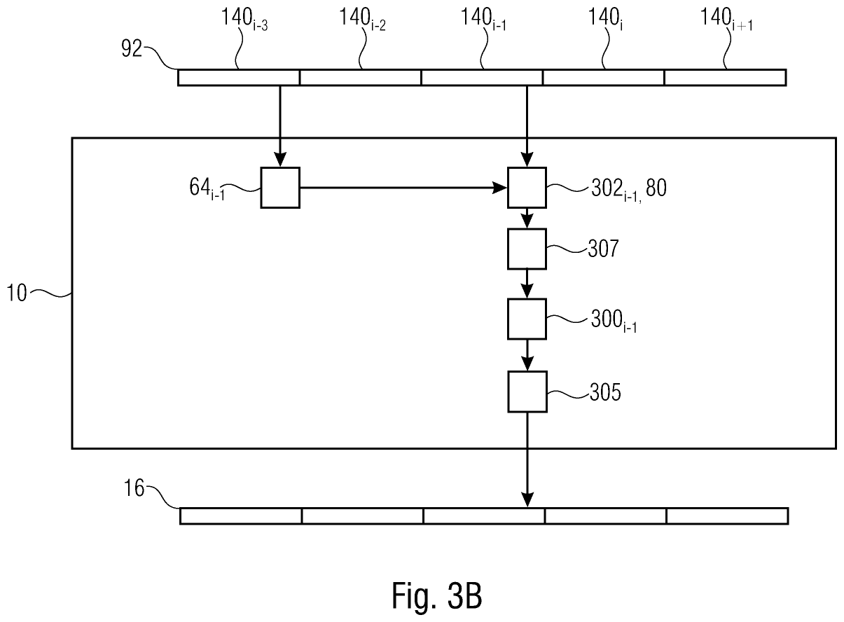

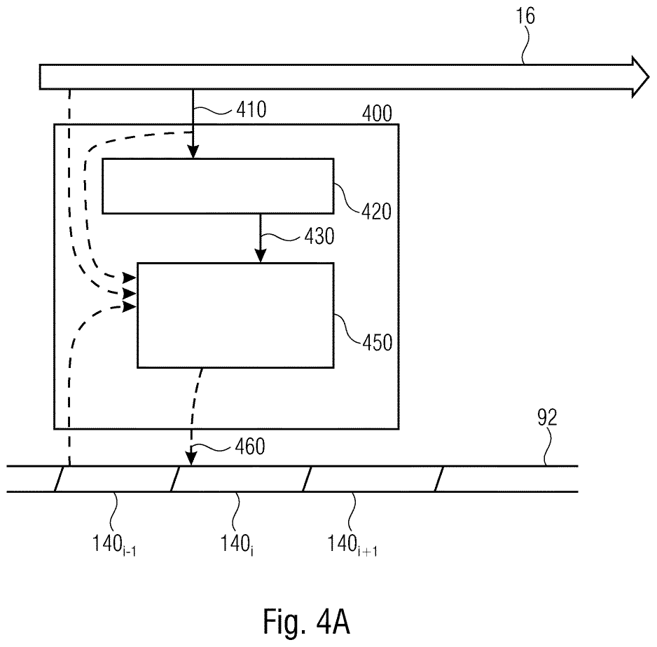

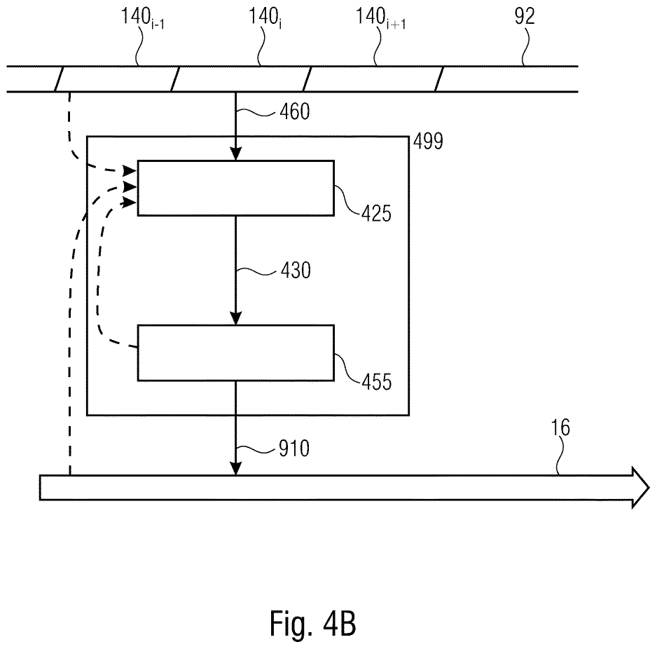

Before preceding with the description of embodiments of aspects of the present application, in the following, a possible functionality of the decoder 200 and encoder 299 shall be described as to how each block is en/decoded, namely using predictive block coding with usage of transform-based residual coding. FIGS. 3a and 3b, thus, represents a kind of generalizing description relative to the possibility that decoder and encoder of FIGS. 2a and 2b operate according to FIG. 1, and although not explicitly stated below, the en/decoder of FIGS. 3a and 3b conform, beyond the coding functionality described now, to the details set out with respect to FIG. 2a-2c. Moreover, for the encoder and the decoder of FIGS. 3a and 3b, the reference signs 10 and 12 of FIG. 1 are re-used for sake of simplicity, as the details set out with respect to these figures shall also be understood as being applicable not only to the encoder/decoder of FIGS. 2a and 2b, but also to the embodiments of FIGS. 4a and 4b.

FIG. 3a illustrates the decoding of a digital time-varying signal 92 from a data stream 16, while the description is easily transferable onto the corresponding encoding task.

According to FIG. 3a, the digital time-varying signal 92 is decoded from the data stream 16 in non-overlapping temporal blocks 140. This is done by decoding each of transform-coded temporal blocks 140ᵢ₋₁ of the non-overlapping temporal blocks 140 of the digital time-varying signal 92 by predicting the respective transform-coded temporal block 140ᵢ₋₁ using a selected prediction mode out of a set of prediction modes to obtain a prediction signal 64ᵢ₋₁ (e.g., in FIG. 4a exemplarily derived from temporal block 140ᵢ₋₃), decoding 304 coefficients 300ᵢ₋₁ from the data stream 16, the coefficients representing a prediction residual signal 80 of the respective transform-coded temporal block 140 in a transform domain, subjecting 306 the coefficients 300ᵢ₋₁ to a predetermined re-transformation from the transform domain to a time domain to obtain a time-domain prediction residual signal 302ᵢ₋₁ representing a prediction residual signal 80 of the respective transform-coded temporal block 140 in a time domain, and correcting 308 the prediction signal 64ᵢ₋₁ using the time-domain prediction residual signal 302ᵢ₋₁, wherein the predetermined re-transformation is a non-overlapping transform. The corrected prediction signal 64ᵢ₋₁ may form the temporal block 140ᵢ₋₁ or may optionally be further processed (e.g., subjected to further prediction and/or filtering).

FIG. 3b illustrates the encoding of a digital time-varying signal 92 into a data stream 16. According to FIG. 4b, the digital time-varying signal 92 is encoded into the data stream 16 in non-overlapping temporal blocks 140 by encoding each of transform-coded temporal blocks 140ᵢ₋₁ of the non-overlapping temporal blocks 140 of the digital time-varying signal 92 by predicting the respective transform-coded temporal block 140ᵢ₋₁ using a selected prediction mode out of a set of prediction modes to obtain a prediction signal 64ᵢ₋₁, subjecting 307 a time-domain prediction residual signal 302ᵢ₋₁ representing a prediction residual signal 80 of the respective transform-coded temporal block 140i in a time domain to a predetermined transformation from the time domain to a transform domain to obtain coefficients 300ᵢ₋₁ representing the prediction residual signal 80 of the respective transform-coded temporal block 140ᵢ₋₁ in the transform domain, and encoding 305 the coefficients 300ᵢ₋₁ into the data stream 16 so as to be used for correcting 308 the prediction signal 64ᵢ₋₁, wherein the predetermined transformation is a non-overlapping transform.

Subsequently, possible variations and implementation details for the coding concept of the encoder 10 (FIG. 3b) and the decoder 12 (FIG. 3a) are described.

The encoder 10 may optionally be configured to correct the prediction signal 64ᵢ₋₁ using the time-domain prediction residual signal in order to obtain a corrected prediction signal 64ᵢ₋₁. The encoder 10 be configured to (e.g., temporally) store the corrected prediction signal 64ᵢ₋₁ (e.g., as potential reference for future predictions).

The transform domain may result from the time domain according to a predetermined transformation (e.g., Tᵢ₋₁, e.g., performed by the encoder 10), wherein the decoder 12 may be configured to select the predetermined transformation out of a set of transformations (e.g. to select the predetermined re-transformation out of a set of re-transformations, e.g., select the transformation matrix), wherein the re-transformation reverses the predetermined transformation (e.g., Tᵢ₋₁⁻¹Tᵢ₋₁=1).

The decoder 12 may be configured to select the set of transformations out of a superset of transformations (e.g. to select the set of re-transformations out of a superset of re-transformations, e.g., select a set transformation matrices out of a superset of transformation matrices) depending on one or more of a length of the respective transform-coded temporal block 140ᵢ₋₁, e.g., a number of total transform coefficients 300ᵢ₋₁, e.g., a number of total non-zero transform coefficients 300ᵢ₋₁), a length of the time domain temporal block 140 (e.g., N, e.g., number of samples of the temporal block), and the selected prediction mode for the respective transform-coded temporal block 140ᵢ₋₁ (e.g., a DC prediction mode, a linear prediction mode, or any other prediction mode disclosed herein).

The set of transformations comprises one or more of one or more discrete cosine transforms, one or more discrete sine transforms, and an identity transform. For example, the set of transformations may comprise a first matrix that realizes a discrete cosine transforms, a second matrix that realizes a discrete sine transform, and a third matrix that realizes an identity transform (e.g., with a value of one on its diagonal, e.g., with values of zero at non-diagonal positions).

The decoder 12 may be configured to skip the subjecting 306 the coefficients to the predetermined re-transformation if the predetermined transformation is the identity transform. For example, transform coefficients 300ᵢ₋₁ may be used by as samples of the temporal block 140ᵢ₋₁, e.g., with optional padding with zeroes.

A sample rate of the digital time-varying signal 92 may be above, or equal to, a Nyquist rate of the transform domain.

For each transform-coded temporal block, a number of the coefficients 300ᵢ₋₁ may coincide with a number of samples of the respective transform-coded temporal block. For example, if a transform-coded temporal block as eight coefficients 300ᵢ₋₁, the temporal block (e.g., in the time domain) may also have eight samples (e.g., or the number of coefficients may be equal to or smaller than the number of samples).

Transform domain may be a critically sampled transform domain. For example, the transform domain may be sampled at a Nyquist rate, e.g., at twice a highest frequency of sample (e.g., within a temporal block or a more general set of samples such as temporal block 30).

The set of prediction modes may comprise one or more of a DC prediction mode, one or more linear prediction modes, a block-copy prediction mode, a cross-channel prediction mode, and a bypass prediction mode.

According to the DC prediction mode, the prediction signal of the respective transform-coded temporal block may be determined to be (and/or, for example, determined by) a constant function with a determination of a constant of the constant function based on predetermined already decoded samples preceding the respective transform-coded temporal block. For example, the constant may be determined based on one or more of an average, sum, and weighted sum of the already decoded samples (and optionally a bias, e.g., for adapting to a rounding shift), e.g., immediately preceding samples, e.g., of K samples, wherein K is an integer number smaller than a number of already decoded samples (e.g., with K being pre-determined, e.g., with K being a power of two).

According to the one or more linear prediction modes, the prediction signal of the respective transform-coded temporal block may be determined to be (and/or, for example, determined by) a linear function with a determination of at least one of a slope and an offset of the linear function based on predetermined already decoded samples preceding the respective transform-coded temporal block. The offset may be determined based on one or more immediately preceding decoded samples, e.g., based on an average or weighted sum. The offset may be determined as or based on a sample immediately preceding the temporal block to be decoded. The slope may be determined based on an extrapolation of immediately preceding samples (e.g., two already decoded samples immediately preceding the temporal block to be decoded). The slope determined from two or more preceding samples may be further modified, for example, reduced (e.g., by a factor of two or four). The one or more linear prediction modes may include one or more of a half-slope prediction and a quarters-lope prediction.

According to the block-copy prediction mode, the prediction signal of the respective transform-coded temporal block may be predicted based on one or more reference block portions of already decoded samples preceding the respective transform-coded temporal block offset relative to the respective transform-coded temporal block at a position signalled for the respective transform-coded temporal block in the data stream. The block-copy prediction mode may be restricted to referencing only the same channel as the temporal block to be predicted (e.g., obtaining only one or more than one reference block portion). The block-copy prediction mode may reference (e.g., perform a prediction based on a referenced block portion, e.g., obtain a reference block portion) more than one channel, e.g., wherein each of the more than one channels may be reference once (or more than once). The block-copy prediction may reference all available channels (e.g., within a set of channels between two random access coded channels). In case of referencing a single reference block portion, samples of the block portion may be copied (or referenced) with a weight of one (e.g., and/or smaller than one). In case of referencing more than one reference block portion, the reference block portions may (e.g., sample-wise) be subjected to a weighted sum (e.g., with equal weights or non-equal weights, e.g., with signalled weights).

According to the cross-channel prediction mode, the prediction signal of the respective transform-coded temporal block may be predicted based on one or more reference coded channels out of coded channels which represent a multi-channel signal 14 coded into the data stream and to be decoded from the data stream by the decoder 12, and one of which is represented by the digital time-varying signal 92.

According to the bypass prediction mode, the prediction signal of the respective transform-coded temporal block is set to zero.

Summarizing, the transform coded into each block 140 relates, according to FIGS. 3a and 3b, along the temporal axis or, differently speaking, in sample domain of the signal 92, to the extension of the respective block 140 only, and does not extend beyond the blocks leading and trailing end. The length signalled in the data stream for each block, thus, also indicates the length of the transform used to code the respective block.

The description now precedes with the description of embodiments according to the second aspect of the invention. Notation used in the FIG. 2a-c shall be used here as well (e.g., qₖ, lₘᵢₙ, lₘₐₓ).

FIG. 4a shows a schematic view of a decoder 400 according to an embodiment according to the second aspect of the invention for decoding a digital time-varying signal 92 from a data stream 16. The decoder can be configured to decode for a predetermined temporal block 140i a selected block length 460 on the basis of length information 410 comprised by the data stream 16. The decoder can contain one or more relative block length parameter determinator 420, that can be configured to determine one or more relative block length parameter 430 on the basis of the length information 410. The decoder can further contain a block length determinator 450, that can be configured to determine the selected block length 460 on the basis of the one or more relative block length parameter 430 and a selected block length 460 of a preceding temporal block 140ᵢ₋₁, that can also be called previous block length. The preceding temporal block may also be called previous block. The block length parameter determinator 450 can, for example, be configured to obtain the previous block length from the data stream 16, the length information 410, the already encoded digital time-varying signal 92 or the one or more relative block length parameter 430. The length information 410 may comprise multiple block length parameter 230 for multiple temporal blocks 140.

FIG. 4b shows a schematic view of an encoder 499 according to an embodiment according to the second aspect of the invention for encoding a digital time-varying signal 92 into a data stream 16. The encoder can be configured to encode a selected block length 460 of a predetermined selected temporal block 140i into the data stream 16. For this, the encoder 499 can comprise a one or more block length parameter determinator 425, that can be configured to determine one or more block length parameter 430 on the basis of a selected block length 460 and a selected block length of a preceding temporal block 140ᵢ₋₁. The decoder can further contain a length information determinator 455, that can be configured to determine a length information 410 on the basis of the one or more block length parameter 430. The one or more block length parameter determinator 425 can, for example, be configured to obtain the selected block length of the preceding temporal block 140ᵢ₋₁ from the block length information determinator 455, the digital time-varying signal 92 or from the already encoded data stream 16.

Note that the en/decoders of FIGS. 4a and 4b might also use a binarization of a block length parameter just as described with respect to FIGS. 2a and 2b, but the association of the bin strings of this binarization to the block lengths may be chosen arbitrary or, in any case, in a different manner than described above with respect to FIGS. 2a and 2b, where the transmission took place in a manner where the length of a certain block was signaled in a manner independent from the previous block's length or, in other words, absolutely. For instance, a smaller bin strings of a non-binary parameter among the one or more block length parameters 430 may be associated with an indication of small changes in block size of the predetermined block 140i compared to the preceding temporal block 140ᵢ₋₁, and longer ones be associated with an indication with larger changes. In other words, the bin string lengths could monotonically increase with the absolute difference in block length between the predetermined block and the previous block. However, it would also be possible that the de/encoders of FIGS. 4a and 4b inherit the functionality according to the first aspect of the invention: one of the parameters 430, such as a non-binary one which may be subject to binarization and might be binarized so that bin strings leading, including the derivation of the block length of the predetermined block based on the length of the previous block, to certain block lengths of the predetermined block are the longer the shorter the block length of the predetermined block, including the derivation of the block length of the predetermined block based on the length of the previous block, is.

In accordance with certain embodiments, de/encoder of FIGS. 4a and 4b may be embodied as follows.

The selected block length 460 lₖ of the predetermined block 140ₖ may be encoded as a factor (e.g., implemented as bit shift) relative to the selected block length of the preceding temporal block 140ᵢ₋₁lₖ₋₁.

For example, a flag (e.g. denoted equal_flag or equality flag/equality_flag) may be encoded and decoded which indicates whether lₖ=lₖ₋₁. If lₖ≠lₖ₋₁ and if l_{k—1}≠lₘᵢₙ and if lₖ₋₁≠lₘₐₓ, another flag (e.g., denoted larger_flag or sign_flag/sign flag) may indicate whether the selected block length 460 lₖ is larger or smaller than the selected block length of the preceding temporal block lₖ₋₁.

A magnitude parameter, comprised by the one or more block length parameter 430 (e.g. a truncated unary codeword) may indicate the number of bitshifts to be applied to lₖ₋₁ in order to yield the selected block length 460 lₖ. If lₖ>lₖ₋₁, left-shifts are used and right-Shifts otherwise.

Truncation of the unary codewords may be utilized, so that signaling the resulting block length (e.g., selected block length 460) is not smaller than the minimum allowed block size (e.g., lₘᵢₙ) and not larger than the maximum allowed block size (e.g., lₘₐₓ). The equal_flag, the larger_flag, and each position in the truncated unary code may use a separate context model. For signaling l0, a predefined value may be assumed for lₖ₋₁ in order to use the same concept for signaling the length of the first block.

Summarizing, the one or more block length parameter 430 may comprise an equality flag, a sign flag and a magnitude parameter. However, the one or more block length parameter may also merely comprise one equality flag. If the equality flag indicates an inequality of the selected block length 460 of the predetermined temporal block 140i and the selected block length of the preceding temporal block 140ᵢ₋₁ a larger flag/sign flag and a magnitude parameter may be de/encoded from/into the one or more block length parameter 430.

Even though the preceding temporal block 140ᵢ₋₁ is indicated as being the directly adjacent preceding temporal block of the predetermine selected temporal block 140ᵢ a different spacing is also possible, e.g., preceding temporal block 140ᵢ₋₂ or generally preceding temporal block 140ᵢ₋ₙ with n∈.

Generally speaking, relating to FIG. 2a-c, FIG. 3a and b and FIG. 4a and b, the digital time-varying signal 92 may be obtained by Electrocardiography, Electroencephalography, Electromyography or seismic measurement, and/or the digital time-varying signal 92 may be a bio-physiological waveform data such as an electroencephalography (EEG) signal, an electrocardiogram (ECG), or an electromyography (EMG) signal, or is a seismic waveform signal. The digital time-varying signal 92 may be (or comprise) a signal (e.g., electrogram) repetitive of (or based on a measurement of) electrophysiological activity, e.g., of a heart, brain, muscles, eyes, or cochlea. The digital time-varying signal 92 may be (or comprise) a signal (e.g., seismogram) repetitive of (or based on a measurement of) vibrations, shaking, or quaking of the ground.

Embodiments discussed above relating to the first and/or second aspect of the invention in FIG. 2a-c, FIGS. 3a and 3b and FIGS. 4a and 4b, have been described in relation to a digital time-varying signal 92 but can also relate to a decoder 12, 200, 400 for decoding a multi-channel digital signal 14, wherein the digital time varying signal 92 may be one of the channels of the multichannel digital signal 14. The decoder 12, 200, 400 may, thus, be configured to decode coded channels representing the multi-channel digital signal 14 from the data stream 16 in temporal blocks 140 with sequentially decoding from the data stream 16 mutually temporally co-located temporal blocks 140 of the coded channels before decoding any subsequent temporal block 140 of the coded channels; and decoding length information 210, 410 from the data stream 16 which may indicate, for each temporal block 140, a selected block length 260, 460 out of a set of block lengths 240. Also, the embodiments can analogously relate to an encoder 10, 299, 499 for encoding a multi-channel digital signal 14 according to an embodiment of the invention. However, a further embodiment of the present application comprises a decoder configured to decode coded channels representing the multi-channel digital signal 14 from the data stream 16 in temporal blocks 140 with sequentially decoding from the data stream 16 mutually temporally co-located temporal blocks 140 of the coded channels before decoding any subsequent temporal block 140 of the coded channels; and decoding length information 210, 410 from the data stream 16 which may indicate, for each temporal block 140, a selected block length 260, 460 out of a set of block lengths 240, wherein the decoding takes place in a manner other than embodied and described with respect to any of FIG. 2a-2c and 4a and 4b, respectively. For instance, the decoder could operate according to FIG. 3, but other than described with respect to any of FIG. 2a-2c and 4a and 4b, respectively. Similar statements are true for the encoder side.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream 16 or a sequence of signals representing the computer program for performing one of the methods described herein. The data stream 16 or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

The reference signs refer to the figures; they are not to be understood as limiting the claims, but are to ease the understanding of the claims; likewise, references to variables and equations in the description shall also not be understood as being limiting, but the portions in the description pertaining the referenced variables and equations might optionally be used to further limit the claims or result into even further subject matter

1. Decoder for decoding a digital time-varying signal from a data stream, configured to
decode the digital time-varying signal from the data stream in temporal blocks; and
decoding length information from the data stream which indicates, for each temporal block, a selected block length out of a set of block lengths,
wherein the decoder is configured to decode the length information from the data stream by
decoding from the data stream, for a predetermined temporal block, a variable-length binarization of a block length parameter comprised by the length information, and
determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

2. Decoder of claim 1,
wherein the variable-length binarization is a truncated unary code and the decoder is configured to determining the selected block length for the predetermined temporal block based on the block length parameter, so that the selected block length is longer the shorter the bin string of the block length parameter is.

3. Decoder of claim 1,
configured to determine the selected block length for the predetermined temporal block based on the block length parameter by deriving an exponent from the block length parameter and determining the selected block length to be 2 to a power determined by the exponent.

4. Decoder of claim 1,
configured to decode the variable length binarization of the block length parameter by binary context-adaptive entropy coding.

5. Decoder of claim 4,
configured to, in decoding the variable length binarization of the block length parameter, use separate context models of each bin position of the variable length binarization.

6. Decoder of claim 1,
configured to decode from the data stream a block-length-set information defining the set of block lengths.

7. Decoder of claim 1,
configured to decode from the data stream an information on a maximum block length, and determine the selected block length for the predetermined temporal block based on the block length parameter by determining the selected block length to be 2 to a power equaling a binary logarithm of the maximum block length minus a subtrahend derived from the block length parameter.

8. Decoder of claim 1,
configured to decode from the data stream an information on a maximum block length, and
determine the selected block length for the predetermined temporal block based on the block length parameter by right-bit-shifting the maximum block length by a number of bit positions which is determined by the block length parameter.

9. Decoder of claim 8,
configured to decode from the data stream an information on a minimum block length, and
wherein the variable length binarization is a truncated unary code and the decoder is configured to determine a truncation parameter of the truncated unary code based on the maximum block length and the minimum block length so that a number of bin strings of the truncated unary code equals a binary logarithm of the maximum block length minus a binary logarithm of the minimum block length plus 1.

10. Decoder of claim 9,
configured to decode from the data stream the information on the minimum block length as an integer indicating the difference between the binary logarithm of the maximum block length minus the binary logarithm of the minimum block length.

11. Decoder of claim 8,
configured to decode from the data stream the information on the minimum block length by decoding a fixed length binarization of an exponent to base 2.

12. Decoder of claim 1,
wherein the set of block lengths exclusively comprises
Powers of 2, or
Powers of 2 and 1.5-fold of powers of 2.

13. Decoder of claim 8,
wherein the decoder is configured to decode the length information from the data stream further by
check whether the selected block length as determined by the block length parameter times 1.5 does not exceed the maximum block length,
if the selected block length as determined by the block length parameter times 1.5 does not exceed the maximum block length,
decoding a flag comprised by the length information from the data stream, and
increasing the selected block length to be 1.5-fold the selected block length as determined by the block length parameter in case of the flag having a first flag state.

14. Decoder of claim 1,
wherein the decoder is configured to decode the length information from the data stream further by
decoding a flag comprised by the length information from the data stream and determining the selected block length for the predetermined temporal block based on the block length parameter and the flag that the selected block length is 1.5 times larger in case of the flag having a first flag state than compared to the flag having a second flag state.

15. Decoder of claim 1, wherein the temporal blocks are non-overlapping and the decoder is configured to
decode each of transform-coded temporal blocks of the temporal blocks of the digital time-varying signal by
predicting the respective transform-coded temporal block using a selected prediction mode out of a set of prediction modes to acquire a prediction signal,
decoding coefficients from the data stream, the coefficients representing a prediction residual signal of the respective transform-coded temporal block in a transform domain,
subjecting the coefficients to a predetermined re-transformation from the transform domain to time domain to acquire a time-domain prediction residual signal representing a prediction residual signal of the respective transform-coded temporal block in a time domain, and
correcting the prediction signal using the time-domain prediction residual signal,
wherein the predetermined re-transformation is a non-overlapping transform.

16. Decoder of claim 1,
wherein the digital time-varying signal is acquired by at least one of Electrocardiography, Electroencephalography, Electromyography or seismic measurement, and/or
wherein the digital time-varying signal is a bio-physiological waveform data such as an electroencephalography (EEG) signal, an electrocardiogram (ECG), or an electromyography (EMG) signal, or is a seismic waveform signal.

17. Encoder for encoding a digital time-varying signal into a data stream, configured to
encode the digital time-varying signal into the data stream in temporal blocks; and
encoding length information into the data stream which indicates, for each temporal block, a selected block length out of a set of block lengths,
wherein the encoder is configured to encode the length information into the data stream by
encoding into the data stream, for a predetermined temporal block, a variable-length binarization of a block length parameter comprised by the length information, and
determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

18. Method for decoding a digital time-varying signal from a data stream, comprising
decoding the digital time-varying signal from the data stream in temporal blocks; and
decoding length information from the data stream which indicates, for each temporal block, a selected block length out of a set of block lengths,
wherein the method comprises decoding of the length information from the data stream by
decoding from the data stream, for a predetermined temporal block, a variable-length binarization of a block length parameter comprised by the length information, and
determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

19. Method for encoding a digital time-varying signal into a data stream, comprising
encoding the digital time-varying signal into the data stream in temporal blocks; and
encoding length information into the data stream which indicates, for each temporal block, a selected block length out of a set of block lengths,
wherein the method comprises encoding of the length information into the data stream by
encoding into the data stream, for a predetermined temporal block, a variable-length binarization of a block length parameter comprised by the length information, and determining the selected block length for the predetermined temporal block based on the block length parameter, so that, for any two block lengths in the set of block lengths, a first bin string of the block length parameter resulting in the determination of a shorter block length of the predetermined temporal block among the two block lengths, is longer, or equally long, than a second bin string of the block length parameter resulting in the determination of a longer block length of the predetermined temporal block among the two block sizes.

20. Data stream encoded using the method according to claim 19.
